(19) United States
(12) Patent Application Publication
(10) Pub. No.: US 2015/0294887 A1
(43) Pub. Date: Oct. 15, 2015

(54) WAFER CONTAINER WITH PARTICLE SHIELD

(71) Applicants: John Burns, Colorado Springs, CO (US); Matthew A. Fuller, Colorado Springs, CO (US); Martin L. Forbes, Divide, CO (US)

(72) Inventors: John Burns, Colorado Springs, CO (US); Matthew A. Fuller, Colorado Springs, CO (US); Martin L. Forbes, Divide, CO (US)

(73) Assignee: ENTEGRIS, INC., Billerica, MA (US)

(21) Appl. No.: 14/115,626

(22) PCT Filed: May 3, 2012
(86) PCT No.: PCT/US12/36373

§ 371 Date: Jul. 16, 2014

Related U.S. Application Data
(60) Provisional application No. 61/482,151, filed on May 3, 2011.

(51) Int. Cl. H01L 21/673

(52) U.S. Cl. CPC H01L 21/67389; H01L 21/67386

(57) ABSTRACT

Particulate shields above the top wafer in wafer containers such as FOUPS prevent accumulation of particulates on wafers. The shields may be formed of materials that are compatible to maintaining less than 5% RH, particularly materials that will not absorb meaningful amounts of water, and that will not bring absorbed moisture into the container, for example cyclic olefin polymers, cyclic olefin copolymers, liquid crystal polymers. A FOUP may be provided with an additional slot above industry standard 25 slots to receive a dedicated barrier. In embodiments, the barrier may be a shape corresponding to a wafer. The barrier may have inherent charge properties opposite to the particulates in the containers to attract the particulates. The barrier may have apertures to facilitate charge development. The barrier may be retrofitted to existing wafer containers. The shield may conform to FOUP configuration.

### RELATED APPLICATION

This application claims the benefit of U.S. Provisional Patent Application No. 61/482,151, filed on May 3, 2011, the disclosure of which is hereby incorporated by reference in its entirety.

### BACKGROUND OF THE INVENTION

Controlling particles and other contaminants has always been of paramount importance in semiconductor processing. As such, wafers that are processed into integrated circuits are stored and transported in enclosed environments, typically front opening boxes, sometimes known as FOUPS (front opening unified pods) and FOSBS (front opening shipping boxes). These wafer containers hold the wafers in spaced stacked arrays and have sealable doors that may be robotically opened. The containers also have features permitting conveyance and robotic access to the wafers. As the circuit sizes have decreased, the importance of the integrity of the wafer containment environment has increased. In advanced semiconductor processing, particularly 40 nm and below, moisture control of the wafers at or below 10% or 5% relative humidity (“RH”) has been found to be very beneficial or critical for desired integrated circuit yields. To control moisture inside the wafer carriers that transport and store wafers gas purge, such as nitrogen, is utilized to replace the ambient atmosphere.

### SUMMARY OF THE INVENTION

Maintaining the wafer containment environment below 5% RH in FOUPS and FOSBS has been discovered to create particulate problems, particularly relating to the top wafer in the spaced stacked arrays, and particularly during transporting FOUPS by their robotic flange located on the top of FOUPS. Means to provide enhanced particulate control, particularly in applications where less that about 5% RH is maintained.

A particulate shield positioned above the top wafer in wafer containers such as FOUPS may be provided to prevent accumulation of particulates on wafers. The particulate shields or barriers may be formed of materials that are compatible to maintaining less than 5% RH, particularly materials that will not absorb meaningful amounts of water, and that will not bring absorbed moisture into the container. In embodiments, particular materials found to be suitable include cyclic olefin polymers, cyclic olefin copolymers, liquid crystal polymers. In particular embodiments, a FOUP may be provided with an additional slot above the industry standard 25 slots to receive a dedicated barrier. In embodiments, the barrier may be a solid thin shape that corresponds to or overlays the wafer shape. In embodiments, the barrier may have inherent charge properties opposite to the particulates found in the containers to thereby attract the particulates to the barrier. In embodiments the barrier may have apertures, such as slots, or other openings, to facilitate charge development for enhancing the attraction of particulates to the barrier. In embodiments the barrier may be retrofitted to existing wafer containers, such as FOUPS. In embodiments, the shield may be conforming to the interior structure of a specific FOUP configuration. In embodiments the 25^{th} slot may be used as a barrier protecting the wafer in the 24^{th} slot from particles shed from the top of the wafer container.

A feature and advantage of embodiments of the invention is that a barrier provides a shield intermediate the robotic flange/shell interface and the uppermost wafer. This region has been discovered to be a source of particles particularly when the wafer container is transported by the robotic flange. Said particles land on said barrier rather than the uppermost wafer.

A feature and advantage of embodiments of the invention is that a barrier may be formed from polycarbonate or polyetherimide or cyclic olefin copolymers, said polymers may be natural or with ultraviolet protection. Said polymers may have carbon powder, carbon fiber, and/or carbon nanotubes.

A feature and advantage of embodiments of the invention is that a barrier may be formed from polyetheretherketone, or liquid crystal polymer. Said polymers may be natural or may have carbon powder, carbon fiber, and/or carbon nano tubes.

A feature and advantage of embodiments of the invention is a process in which a container is purged with a purging gas, such as nitrogen, to maintain a RH below 5%, and further a barrier is provided to control particulates on the upper most wafers, the process may include the use of select materials for maintaining the RH below 5%. The select materials may be in the barrier. The select materials may also include other portions of the wafer container or the entirety or substantially the entirety of the wafer container. The select materials may be cyclic olefin polymers, cyclic olefin copolymers, liquid crystal polymers, polyetheretherketones.

Embodiments of the invention include a front opening wafer container with an additional slot for a barrier, a retrofitted barrier, a slotted barrier, an apertured barrier, a barrier conforming to the structural configuration of the container, a container with a plurality of barriers.

A feature and advantage of particular embodiments of the invention is that particulate control is provided for the top wafer in a front opening wafer container where the RH of the wafer container is maintained below 5%. The particulate control comprising a shield extending horizontally in a position directly above the uppermost wafer and positioned below the top wall structure of the wafer container.

A feature and advantage of particular embodiments is that apertures in the particle shield facilitate air or gas flow through the barrier allowing the shield to develop a charge from the gas passing against the surfaces of the shield.

### DESCRIPTION OF THE FIGURES

FIG. 1 is a perspective view of a wafer container known as a FOUP which is suitable for the invention herein.

FIG. 2 is a perspective view of a container portion of a wafer container with a 26th slot and a particle shield for insertion therein.

FIG. 3 is an exploded perspective view of a FOUP with a particle shield suitable for assembly therewith or for retrofit.

FIG. 4 is a perspective view of a wafer shield suitable for retrofit on an assembled FOUP as is shown is FIG. 1

FIG. 5 is a top plan view illustrating the wafer shield of FIG. 4 on the interior wafer support structure of the FOUP of FIGS. 1 and 3.

FIG. 6 is a perspective view looking upwardly into the container portion of a FOUP according to a configuration consistent with FIGS. 1 and 3, also showing a portion of the bottom of said FOUP.

### DETAILED DESCRIPTION

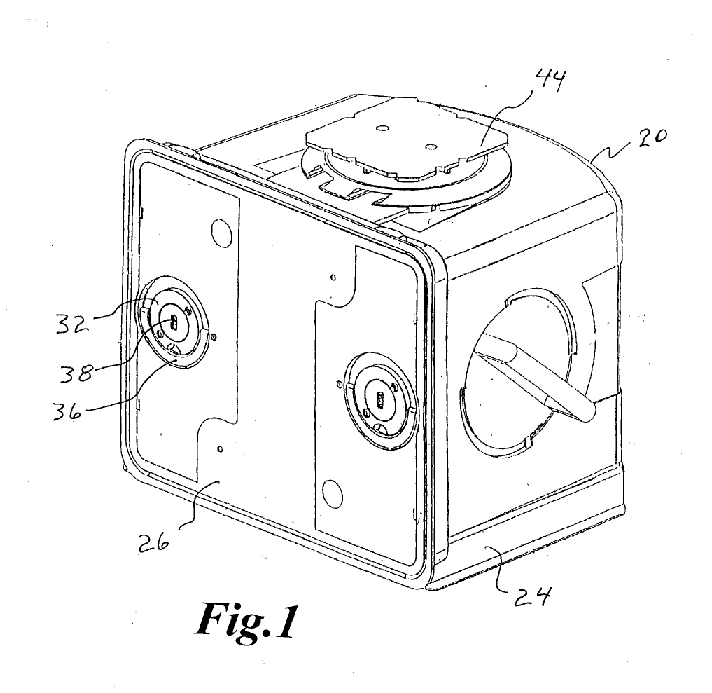

Referring to FIGS. 1, 2, and 3, a front opening wafer container 20 known as a FOUP is illustrated and comprises generally a container portion 24 and a door 26. The container portion has a an open front 27 and a door frame 27.2 sized to receive the door 26. The container portion having a top 27.6 with a top wall 27.8, a pair of sidewalls 28, a backside 28.6 with a backside wall 28.8, and a bottom 29 with a three groove kinematic coupling 30. The door sealingly engages with the container portion and latches by way of a pair of latch mechanisms 32. The door of FIG. 1 having manual handles 36 and keyholes 38 exposed on the front side 40 of the door. A robotic flange 44 is attached to the top of the container portion and is used for overhead transport of the wafer container during processing of the wafers therein. The components may be conventionally formed from injected molded thermoplastics such as polycarbonate. In other embodiments, components may be formed of low moisture absorbent material, one of or combinations of a cyclic olefin polymer, cyclic olefin copolymer, liquid crystal polymer, and polyetheretherketone.

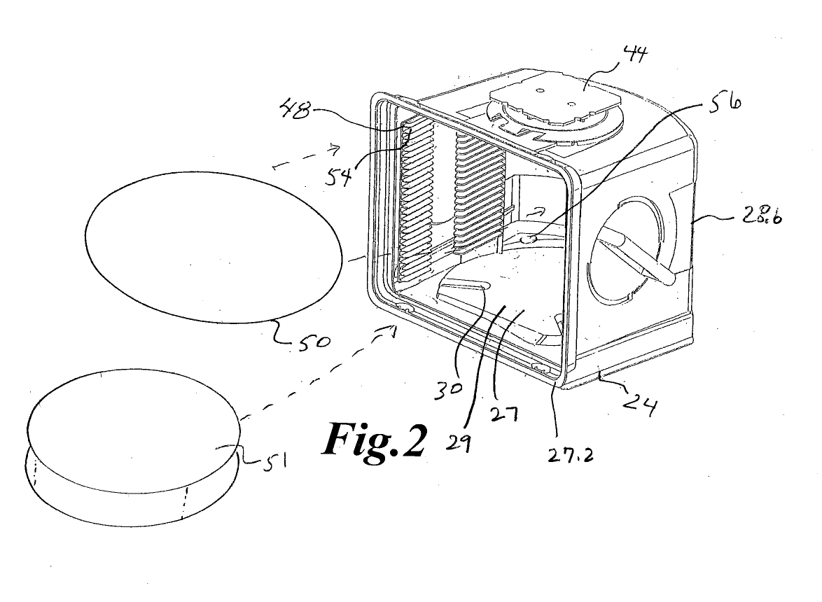

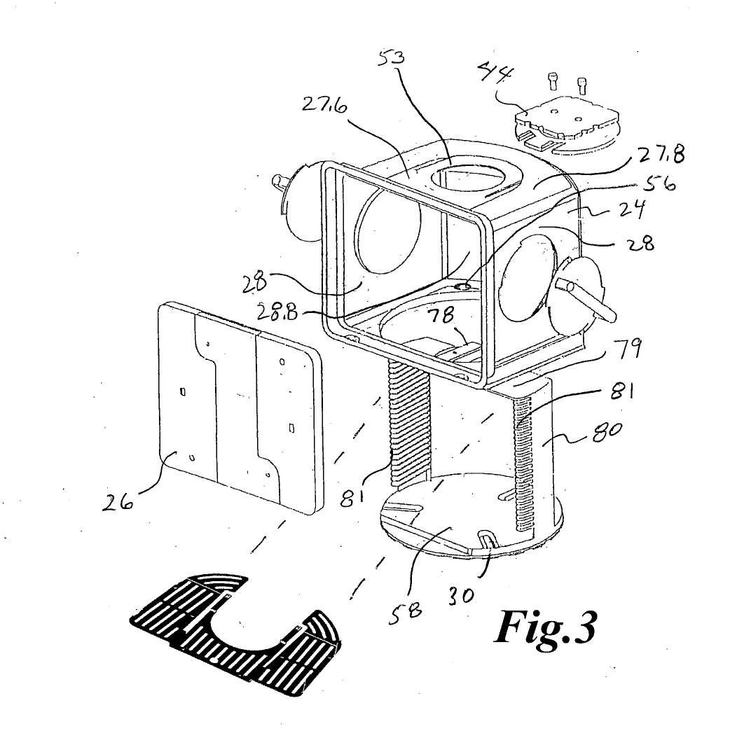

Referring to FIGS. 2 and 3, the container portion has an additional slot 48 dedicated to receiving a particle shield 50. Said slot may be the 26th slot, one more than the conventional and industry standard number of slots in 300 mm wafer containers such as the configuration illustrated. In other embodiments, the 25^{th} slot may be sacrificed for the particle shield. The slots below the slot with the particle shield receive the wafers 51. The shield is spaced from the top wall and the uppermost wafer for collecting or preventing particles generated from or originating from the top of container portion from landing on the uppermost wafer. In certain instances the stress imparted to the top wall structure 53 by the transporting the container by the robotic flange can generate or release particles from the top wall structure.

The particle shield may be configured to directly correspond to the size and shape of the wafers that will be received in the container and will be directly above the wafer in the 25th slot, the uppermost wafer slot 54. In embodiments the shield may be shaped to substantially overlay the uppermost wafer. In embodiments, the particle shield may be slightly larger than the wafers to be contained in the wafer container. That is, about 0.5 to 2% greater in diametric measurement. In other embodiments, 2 to 5% larger in diametric measurement.

The wafer container has purge ports 56 for purging the interior of the wafer container when closed. Such purge ports may be located at the front or rear of the container portion typically on the bottom of same outside the kinematic couple plate 58. Ports such as disclosed in U.S. Pat. No. 7,328,727 owned by the owner of this invention disclose suitable configurations of purge ports. Said patent is incorporated by reference herein.

The shield may be formed of a material having an inherent charge that is opposite to the charges carried by particles in the wafer container. Such opposite charge will cause the particles to be attracted to the shield and adhere thereto. The shield may also be formed of a material highly resistant to absorption of moisture, for example, cyclic olefin polymers, cyclic olefin copolymers, liquid crystal polymers, and polyetheretherketones.

The shield may be formed of any one of these materials or any combination of these materials or any of the materials in combination with other materials. The shield may also have conductive and/or static dissipative characteristics, provided by addition carbon powder, carbon fibers, and/or carbon nanotubes. By seating on a shelf in the 26th slot, with the shelf also being of a conductive material or at least static dissipative, and connected to ground, the shield will be effectively grounded.

In an application where the RH of the interior of the container is being maintained at low humidity level, for example less that 10% or less than 5%, use of the above materials helps to maintain the low RH. In embodiments, purge can lower the RH to less than 10% where it is maintained for at least 30 minutes. In embodiments, purge can lower the RH to less than 5% where it is maintained for at least 30 minutes. In embodiments, purge can lower the RH to less than 10% where it gradually ramps up. In embodiments, purge can lower the RH to less than 5% where it then gradually ramps up. Such low RH has been discovered to create a tendency to promote generation of particles, particularly at the top of interior of the container portion adjacent to the robotic flange 44 and associated with overhead transport of the container by way of the robotic flange. The presence of the shield overlaying the uppermost wafer precludes particles generated or present above the stack of wafers from falling on the uppermost wafer. The shield being formed of a low moisture absorbing material minimizes the ramp up of RH in the wafer container.

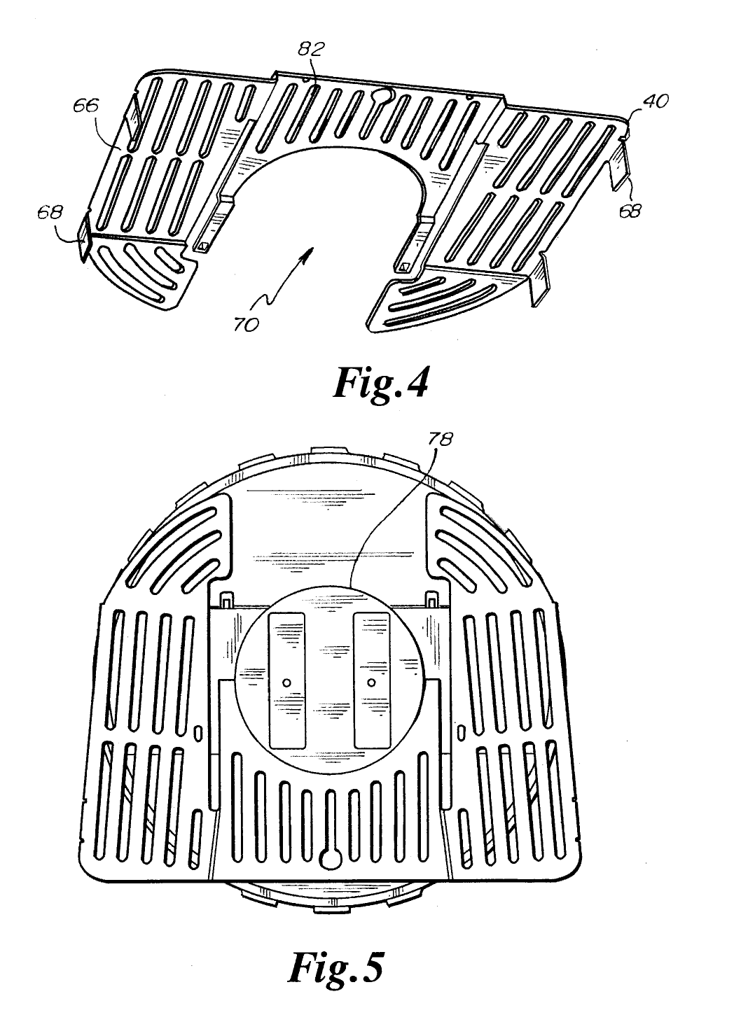

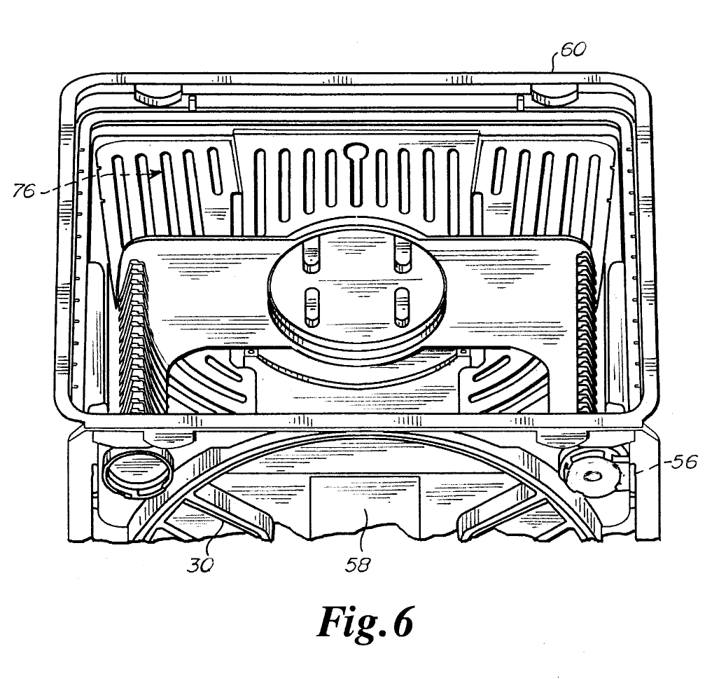

Referring to FIGS. 3, 4, 5, and 6, another embodiment of a wafer container 60 with associated particle shield 64 is illustrated. This shield may be sized to conform to the configuration of the F300 FOUP manufactured by Entegris, Inc. the owner of the instant application. The shield has a body portion 66 and tabs 68 and a central slot 70. The shield is conformed to the top inside structure 76 of the F300 FOUP. The slot 70 fits around support structure, specifically the upper portion 78 on bridging member 79 of the wafer cassette portion 80 that attaches to the robotic flange 44 on the exterior of the container portion 24. The wafer cassette portion has two sets 81 of wafer shelves connected by the bridging member. The slot 70 may be sized to be an interference fit such that the shield is retained in position. Alternatively detents, tangs, pawls, or fasteners may be utilized to retain the shield in place.

In addition to 300 mm wafer containers such a FOSB, the invention is suitable as well for 450 mm wafer containers, particularly those that utilize robotic flanges on the tops of the containers for transport.

This shield has apertures or openings configured as slots 82 that present a grate configuration. This allows purge gas or ambient atmosphere to pass through the apertures enhancing the gas to surface contact which is believed to increase the charge of the shield thus increasing the attraction of particles to the shield. The shield is positioned over the upper most wafer slot. In an alternative embodiment, two plates may over lay each other such that openings in one plate are horizontally offset from the openings in the other plate providing no direct vertical path for particles from above the two plates to the uppermost wafer. In another embodiment the apertures may angle from vertical such that no direct path or a reduced direct path for particles from the top of the wafer container to the wafer is provided whilst still allowing air or gas to pass through the plate for inducing a charge. In another embodiment, a plate may have two or more levels of particle collecting surfaces separated by vertical gaps through which the air or gas may pass through. Such air or gas may pass through the plate during purging or opening and/or closing of the door.

The particle shield may be sized to substantially overlay the wafer or entirely overlay the wafer. “Substantially” when used herein means more than 75%, that is, at least 75% of the area of the wafer is covered, by being directly vertically above the wafer, by the particle shield. In other embodiments, the top surface of the wafer will be 90% covered by the particle shield. In other embodiments, the particle shield will cover 100% of the wafer top surface area.

The particle shield may be placed such that there is a gap or a clearance of at least 1 cm between the particle shield and the uppermost wafer. In embodiments the clearance between the particle shield and the uppermost wafer is between 1 cm and 3 cm. In embodiments, there is a gap or clearance between the top wall structure and the particle shield of at least 0.5 cm. In embodiments, there is a gap between the top wall structure and the particle shield of at least 1 cm. In embodiments, there is a gap between the top wall structure and the particle shield of between 0.5 cm. and 2 cm.

This shield configuration also may be formed of a material having an inherent charge that is opposite to the charges carried by particles in the wafer container. Such opposite charge will cause the particles to be attracted to the shield and adhere thereto. The shield may also be formed of a material highly resistant to absorption of moisture, for example, cyclic olefin polymers, cyclic olefin copolymers, liquid crystal polymers, and polyetheretherketones. The shield may also have conductive and/or static dissipative characteristics, provided by addition carbon powder, carbon fibers, and/or carbon nanotubes. By engaging with the wafer cassette portion, and where the wafer cassette portion is formed of a conductive material or at least static dissipative, and connected to ground, the shield will be effectively grounded. In embodiments, the shield may be formed of metal.

Wafer container, seals, features, and other wafer container structure and components are illustrated in U.S. Pat. Nos. RE 38,221; 6,010,008; 6,267,245; 6,736268, 5,472,086; 5,785,186; 5,755,332; and PCT Publications. WO 2008/008270; WO 2009/089552. The patents and inventions of the publications are owned by the owner of the present application. Also, see U.S. Pat. No. 5,346,518 illustrating vapor removing elements. These patents and the publications are incorporated by reference herein.

The present invention may be embodied in other specific forms without departing from the spirit or essential attributes thereof; and it is, therefore, desired that the present embodiment be considered in all respects as illustrative and not restrictive, reference being made to the appended claims rather than to the foregoing description to indicate the scope of the invention.

1. A wafer container with enhanced particle protection comprising a container portion with an open front and a door sized to close the open front, the container portion having a top with a top wall, a pair of sidewalls, a backside with a backside wall, and a bottom with a three groove kinematic coupling outwardly exposed, the top wall, the sidewalls, the backside wall, the bottom defining an open interior, the container portion further comprising two sets of opposing shelves located in the open interior at each side of the container portion defining a plurality of slots, including an uppermost slot, for receiving wafers through the open front, the wafer container further comprising a robotic flange extending upwardly from the container portion at the top of the container portion,
the wafer container further comprising a particle shield configured generally as a flat plate, the particle shield attached to the container portion in the open interior at the top of the container portion opposite the robotic flange and spaced from the top wall, thereby collecting particles generated at the top wall and preventing them from falling on a wafer in the uppermost slot.

2. The wafer container of claim 1 wherein the plate includes a plurality of apertures configured as a plurality of slots.

3. The wafer container of claim 1 wherein the particle shield has a perimeter that conforms to and follows the backside wall, the sidewalls, and the open front and is sized to at least substantially overlay a wafer in the uppermost wafer slot.

4. The wafer container of claim 1 wherein the shield is formed of one of cyclic olefin polymers, cyclic olefin copolymers, liquid crystal polymers, and polyetheretherketones.

5. The wafer container of claim 1 wherein the two sets of opposing shelves connect to one another at the top of the wafer container in the interior of the wafer container by way of a bridging member, the two sets of opposing shelves and bridging member being unitary with one another, and wherein the robotic flange engages with the bridging member.

6. The wafer container of claim 1 wherein the shield is retained in place by one of the set of interference fit, tangs, pawls, and a detent mechanism.

7. A method of providing enhanced particle protection in a wafer container comprising:
providing a purge to a front opening wafer container to a relative humidity in the wafer container below 5%;
transporting the wafer container by way of a robotic flange on the top of the wafer container whereby particles are generated at the top of the wafer container in the interior of the wafer container;
providing a barrier between the uppermost wafer in the wafer container and the top of the wafer container by positioning a particle shield therebetween and supporting the wafer shield by the wafer container.

8. The method of claim 7 further comprising providing the wafer shield comprised of a low moisture absorbent material formed from at least one of a cyclic olefin polymer, cyclic olefin copolymer, liquid crystal polymer, and a polyetheretherketone.

9. The method of claim 7 further comprising providing a charge to the particle barrier that differs from the charge on the wafers whereby particles are attracted to the particle barrier rather than the wafers.

10. The method of claim 9 further comprising providing the barrier with a plurality of apertures for generating a charge by way of one of gas or air passing through the plurality of apertures.

11.-17. (canceled)

18. A wafer container with enhanced particle protection comprising a container portion with an open front and a door sized to close the open front, the container portion having a top with a top wall, a pair of sidewalls, a backside with a backside wall, and a bottom with a three groove kinematic coupling outwardly exposed, the top wall, the sidewalls, the backside wall, the bottom defining an open interior, the container portion further comprising two sets of opposing shelves located in the open interior at each side of the container portion defining a plurality of slots, including an uppermost slot, for receiving wafers through the open front, the wafer container further comprising a robotic flange extending upwardly from the container portion at the top of the container portion and a pair of purge ports for purging the wafer container,
the wafer container further comprising a particle shield configured generally as a flat plate opposite the robotic flange and spaced from the top wall and space from the uppermost slot and sized to substantially shield a wafer in the uppermost slot from the top wall, thereby collecting particles originating at the top wall and substantially preventing them from falling on the wafer in the uppermost slot.

19. A method providing enhanced particle protection to wafers in the wafer container of claim 18 during transport by way of a robotic flange on the top of the wafer container, the method comprising: maintaining a low RH of less that 10% in the wafer container for more than 30 minutes.

20. The method of claim 19 further comprising providing the wafer shield comprised of a low moisture absorbent material formed from at least one of a cyclic olefin polymer, cyclic olefin copolymer, and liquid crystal polymer, and a polyetheretherketone.

21. The method of claim 19 or 20 further comprising providing the wafer shield with a charge to attract particles.

22. The wafer container of claim 18 wherein the shield is formed of one of cyclic olefin polymers, cyclic olefin copolymers, liquid crystal polymers, and polyetheretherketones.

23. The wafer container of claim 18 wherein the plate includes a plurality of apertures configured as a plurality of slots.

24. The wafer container of claim 18 wherein the plate includes a plurality of apertures configured as a plurality of slots.
